(19) United States
(12) Patent Application Publication
(10) Pub. No.: US 2023/0214558 A1
(43) Pub. Date: Jul. 6, 2023

(54) CONSTRUCTION REPAIR SUPPORT APPARATUS, METHOD, AND PROGRAM

(71) Applicant: FUJIFILM Corporation, Tokyo (JP)

(72) Inventor: Makoto OZEKI, Tokyo (JP)

(73) Assignee: FUJIFILM Corporation, Tokyo (JP)

(21) Appl. No.: 18/183,779

(22) Filed: Mar. 14, 2023

Related U.S. Application Data
(63) Continuation of application No. PCT/JP2021/034507, filed on Sep. 21, 2021.

(30) Foreign Application Priority Data
Sep. 25, 2020 (JP) 2020-160940

(51) Int. Cl. G06F 30/27; G06N 3/0464; G06F 30/13; G06Q 50/08

(52) U.S. Cl. CPC G06F 30/27; G06N 3/0464; G06F 30/13; G06Q 50/08; E01D 22/00

(57) ABSTRACT

There are provided a construction repair support apparatus, a construction repair support method, and a construction repair support program with which repair design information for a construction can be automatically generated and the determination basis for the repair design information can be presented to the user. A construction repair support apparatus includes a processor, and the processor is configured to perform an information acquisition process of acquiring construction information concerning a construction, a repair design information generation process of generating repair design information concerning a repair of damage in the construction on the basis of the construction information and damage information concerning the damage in the construction, a determination basis generation process of generating information that contributes to generation of the repair design information, as determination basis information for the repair design information, and a display process of causing a display device to display the repair design information and the determination basis information.

### CROSS-REFERENCE TO RELATED APPLICATIONS

The present application is a Continuation of PCT International Application No. PCT/JP2021/034507 filed on Sep. 21, 2021 claiming priority under 35 U.S.C § 119(a) to Japanese Patent Application No. 2020-160940 filed on Sep. 25, 2020. Each of the above applications is hereby expressly incorporated by reference, in its entirety, into the present application.

### BACKGROUND OF THE INVENTION

### 1. Field of the Invention

The present invention relates to a construction repair support apparatus, a construction repair support method, and a construction repair support program and specifically relates to a technique for presenting the determination basis for repair design information for a construction when the repair design information is automatically generated.

### 2. Description of the Related Art

To address labor shortages and increased costs caused by obligated inspections of constructions including bridges and tunnels, ICT (Information and Communication Technology) are being increasingly used in maintenance of constructions.

For example, automatic generation of repair design information by using artificial intelligence (AI) and by learning structural data, damage data, and repair data of constructions is being studied.

When repair design information is automatically generated by using a computer, it is difficult to search for the determination basis for the repair design information, and the details of processing specifically in machine learning and AI are a black box, and therefore, the process of determination is unknown and the user is unable to understand and be convinced of the repair design information, which is a problem.

In the related art, an inference apparatus that infers a class among predetermined classes to which an input image belongs, by inference using a neural network has been proposed (JP2019-82883A).

The inference apparatus includes: an input unit; a frequently appearing feature value database in which frequently appearing feature values that frequently appear in an inference process in a neural network are classified into classes and stored; an inference unit that infers a class to which an input image belongs, by inference using the neural network; a representative feature value extraction unit that extracts feature values appearing in an inference process in the inference and extracts feature values, among the feature values, that satisfy a predetermined condition as representative feature values; a basis feature value extraction unit that extracts basis feature values on the basis of the frequently appearing feature values and the representative feature values; and an output unit that outputs the basis feature values together with the inferred class.

The basis feature value extraction unit extracts the intersection of two sets, namely, the set of the frequently appearing feature values and the set of the representative feature values, as the basis feature values.

### SUMMARY OF THE INVENTION

For the inference apparatus described in JP2019-82883A, the frequently appearing feature value database in which frequently appearing feature values that frequently appear are classified into classes and stored needs to be prepared. Further, JP2019-82883A does not describe automatic generation of repair design information for a construction or indicate a new issue that, specifically when repair design information is automatically generated, the user is unable to understand and be convinced of the determination basis for the repair design information.

In one embodiment of the technique of the present disclosure, there are provided a construction repair support apparatus, a construction repair support method, and a construction repair support program with which repair design information for a construction can be automatically generated and the determination basis for the repair design information can be presented to the user.

A construction repair support apparatus according to a first aspect of the present invention is a construction repair support apparatus including a processor, the processor being configured to perform an information acquisition process of acquiring construction information concerning a construction, a repair design information generation process of generating repair design information concerning a repair of damage in the construction on the basis of the construction information and damage information concerning the damage in the construction, a determination basis generation process of generating information that contributes to generation of the repair design information, as determination basis information for the repair design information, and a display process of causing a display device to display the repair design information and the determination basis information.

According to the first aspect of the present invention, when repair design information concerning a repair of damage in a construction is automatically generated, determination basis information that is information contributing to generation of the repair design information is generated and the determination basis information is presented, and therefore, the user can easily understand the determination basis for the repair design information.

In the construction repair support apparatus according to a second aspect of the present invention, preferably, the processor is configured to acquire positional information about the damage in the construction, and cause the display device to display the repair design information in association with the positional information. Accordingly, the user can grasp the position of the damage in the construction to which the repair design information corresponds.

In the construction repair support apparatus according to a third aspect of the present invention, preferably, the construction information includes three-dimensional information that indicates the entire construction, and the processor is configured to cause the display device to display the construction three-dimensionally on the basis of the three-dimensional information, and cause the repair design information to be displayed at a corresponding position on the three-dimensionally displayed construction, on the basis of the positional information about the damage.

Accordingly, the user can grasp the position of the damage to which the repair design information corresponds, on the three-dimensionally displayed construction.

In the construction repair support apparatus according to a fourth aspect of the present invention, preferably, the processor is configured to perform a process of accepting switching between overall display and local display of the construction, and the processor is configured to in response to accepting switching from the overall display to the local display and the positional information about the damage, switch display on the display device from the overall display of the construction based on the three-dimensional information to the local display that includes an image of a position indicated by the positional information about the damage, and cause the display device to display the determination basis information associated with the positional information about the damage, and in response to accepting switching from the local display to the overall display, switch display on the display device to the overall display, and cause the display device to display the repair design information in association with the positional information about the damage.

According to the fourth aspect of the present invention, display can be switched between the overall display of the construction based on the three-dimensional information and the local display, and the user can confirm on the overall display, the repair design information associated with the positional information about the damage and can confirm the determination basis information for the repair design information on the local display.

Preferably, the construction repair support apparatus according to a fifth aspect of the present invention further includes a database that stores the construction information and the damage information, in which the processor is configured to perform a damage information generation process of generating the damage information on the basis of a two-dimensional image of the construction included in the construction information, and store the damage information in the database in association with the construction information, and in the information acquisition process, the construction information and the damage information associated with the construction information are acquired from the database.

Preferably, the construction repair support apparatus according to a sixth aspect of the present invention further includes a database that stores the construction information, in which in the information acquisition process, the construction information is acquired from the database, and in the repair design information generation process, the damage information is generated on the basis of a two-dimensional image of the construction included in the construction information, the construction information being acquired in the information acquisition process, and the repair design information concerning a repair of the damage in the construction is generated on the basis of the construction information and the damage information.

In the construction repair support apparatus according to a seventh aspect of the present invention, preferably, in response to acquiring a plurality of pieces of determination basis information including the determination basis information, the processor is configured to calculate pieces of degree-of-contribution information that respectively indicate percentages of contribution of the plurality of pieces of determination basis information to generation of the repair design information, and cause the display device to display the pieces of degree-of-contribution information respectively corresponding to the plurality of pieces of determination basis information. Accordingly, the user can confirm which piece of determination basis information contributes to generation of the repair design information to what degree and can reflect the confirmation to, for example, a repair method.

In the construction repair support apparatus according to an eighth aspect of the present invention, preferably, the determination basis information includes region information about a region, on the construction, to which attention is to be paid. The region information, about a region on the construction, contributing to generation of the repair design information can be presented as basis information for the repair design information.

In the construction repair support apparatus according to a ninth aspect of the present invention, preferably, in the repair design information generation process, the repair design information is generated on the basis of pieces of damage information at a plurality of time points, and the determination basis information includes a degree of a change over time in the pieces of damage information between the plurality of time points. Accordingly, the degree of development of damage can be used as basis information for the repair design information.

In the construction repair support apparatus according to a tenth aspect of the present invention, preferably, the processor is configured to perform a process of accepting specifying of the repair design information by a user, and in response to accepting specifying of the repair design information, cause the display device to display the determination basis information corresponding to the repair design information.

In the construction repair support apparatus according to an eleventh aspect of the present invention, preferably, the processor is configured to perform a process of accepting specifying of the determination basis information by a user, and in response to accepting specifying of the determination basis information, cause the display device to display the repair design information corresponding to the determination basis information.

In the construction repair support apparatus according to a twelfth aspect of the present invention, the processor includes a first learning model configured to perform the repair design information generation process, and the first learning model outputs the repair design information in response to input of the construction information or input of the construction information and the damage information.

In the construction repair support apparatus according to a thirteenth aspect of the present invention, preferably, in the determination basis generation process performed by the processor, a calculation process for an output result of the first learning model is traced back and the determination basis information that affects the output result is extracted.

In the construction repair support apparatus according to a fourteenth aspect of the present invention, the processor includes a second learning model configured to perform the damage information generation process, and the second learning model outputs the damage information about the construction in response to input of a two-dimensional image of the construction.

In the construction repair support apparatus according to a fifteenth aspect of the present invention, preferably, the construction information includes at least one of drawing information about the construction, three-dimensional information that indicates the entire construction, a two-dimensional image that shows a local part of the construction, or text information concerning the construction.

In the construction repair support apparatus according to a sixteenth aspect of the present invention, preferably, the construction information includes at least one of structural information, repair history information, environmental information, or monitoring information about the construction.

In the construction repair support apparatus according to a seventeenth aspect of the present invention, preferably, the repair design information includes at least one of a cause of damage, a countermeasure method, a degree of soundness, necessity of repair, degradation prediction, or a countermeasure category.

In the construction repair support apparatus according to an eighteenth aspect of the present invention, preferably, the determination basis information includes at least one of the damage information, the construction information, or environmental information.

In the construction repair support apparatus according to a nineteenth aspect of the present invention, preferably, the damage information includes at least one of a damage type, a damage shape, a degree of damage, a degree of development of damage, a damaged region, a damage position, or similar damage.

A construction repair support method according to a twentieth aspect of the present invention is a construction repair support method for a processor to perform a step of acquiring construction information concerning a construction, a step of generating repair design information concerning a repair of damage in the construction on the basis of the construction information and damage information concerning the damage in the construction, a step of generating information that contributes to generation of the repair design information, as determination basis information for the repair design information, and a step of causing a display device to display the repair design information and the determination basis information.

A construction repair support program according to a 21st aspect of the present invention is a construction repair support program for causing a computer to implement a function of acquiring construction information concerning a construction, a function of generating repair design information concerning a repair of damage in the construction on the basis of the construction information and damage information concerning the damage in the construction, a function of generating information that contributes to generation of the repair design information, as determination basis information for the repair design information, and a function of causing a display device to display the repair design information and the determination basis information.

According to the present invention, when repair design information for a construction is automatically generated, the determination basis for the repair design information can be presented. Accordingly, the user can understand and be convinced of the automatically generated repair design information and can refer to the determination basis for the repair design information upon a repair of the construction.

### BRIEF DESCRIPTION OF THE DRAWINGS

FIG. 1 is a block diagram illustrating an embodiment of a hardware configuration of a construction repair support apparatus according to the present invention;

FIG. 2 is a block diagram illustrating a first embodiment of a construction repair support apparatus according to the present invention;

FIG. 3 is a table illustrating a list of determination results and determination basis information for various repair design items;

FIG. 4 is a diagram illustrating a flow in which a CNN infers a determination result for a cause of damage (forward propagation);

FIG. 5 is a diagram illustrating a flow in which the CNN infers from the determination result for the cause of damage, the determination basis for the determination result (back propagation);

FIG. 6 is a diagram illustrating cross-reference relationships between determination results and determination bases;

FIG. 7 is a diagram illustrating a first example of determination basis presentation displayed on an output unit;

FIG. 8 is a diagram illustrating a second example of determination basis presentation displayed on the output unit;

FIG. 9 is a diagram illustrating a third example of determination basis presentation displayed on the output unit;

FIGS. 10A and 10B are diagrams illustrating switching between overall display of a construction displayed three-dimensionally and local display;

FIG. 11 is a diagram illustrating an example of a list of text information of repair design information and text information of determination basis information that are associated with each other in the list;

FIG. 12 is a block diagram illustrating a second embodiment of a construction repair support apparatus according to the present invention; and

FIG. 13 is a flowchart illustrating an embodiment of a construction repair support method according to the present invention.

### DESCRIPTION OF THE PREFERRED EMBODIMENTS

Hereinafter, preferred embodiments of a construction repair support apparatus, a construction repair support method, and a construction repair support program according to the present invention will be described with reference to the attached drawings.

### Hardware Configuration of Construction Repair Support Apparatus

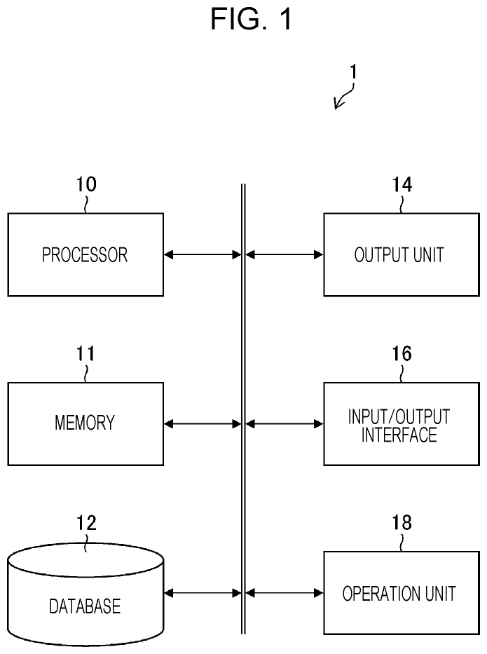

FIG. 1 is a block diagram illustrating an embodiment of a hardware configuration of a construction repair support apparatus according to the present invention.

As illustrated in FIG. 1, a construction repair support apparatus 1 can be formed of, for example, a personal computer or a workstation and includes a processor 10, a memory 11, a database 12, an output unit 14, an input/output interface 16, and an operation unit 18.

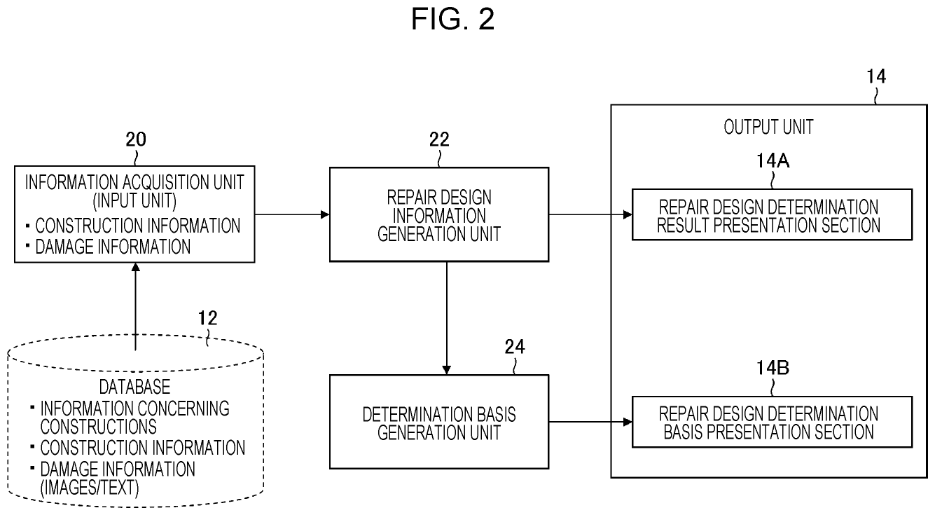

The processor 10 is formed of a CPU (central processing unit) and so on, centrally controls units of the construction repair support apparatus 1, and functions as, for example, an information acquisition unit (input unit) 20, a repair design information generation unit 22, and a determination basis generation unit 24 illustrated in FIG. 2.

The repair design information generation unit 22 is a unit that generates repair design information concerning a repair of damage in a construction, on the basis of, for example, construction information concerning the construction, and the determination basis generation unit 24 is a unit that generates information contributing to generation of the repair design information, as determination basis information for the repair design information. The repair design information generation unit 22, the determination basis generation unit 24, and so on will be described in detail below.

The memory 11 includes a flash memory, a ROM (read-only memory), and a RAM (random access memory). The flash memory and the ROM are nonvolatile memories that store, for example, an operating system and various programs including a construction repair support program according to the present invention. The RAM functions as a work area for processing by the processor 10. The RAM temporarily stores, for example, the construction repair support program stored in, for example, the flash memory. Note that the processor 10 may include a part (RAM) of the memory 11.

The processor 10 controls the units of the construction repair support apparatus 1 and performs processes in accordance with the construction repair support program while using the RAM as a work area.

The database 12 is a unit that stores and manages information concerning constructions. Here, information concerning constructions include construction information concerning constructions and damage information concerning damage in constructions. The construction information and the damage information in this example will be described in detail below.

The output unit 14 is a display device that displays repair design information generated by the construction repair support apparatus 1 and determination basis information that contributes to generation of the repair design information. The output unit 14 performs overall display of, for example, a three-dimensional image that shows the entire construction, local display of a two-dimensional image that shows a local part of a construction, and display of, for example, a damage image and a damage diagram, and is further used as part of a user interface for accepting an instruction from the user.

The input/output interface 16 includes a connection unit that can be connected to an external device and a communication unit that can be connected to a network. To the connection unit that can be connected to an external device, for example, USB (Universal Serial BUS) or HDMI (High-Definition Multimedia Interface) (HDMI is a registered trademark) can be applied.

The construction repair support apparatus 1 can acquire, for example, construction information concerning a desired construction and damage information concerning damage in the construction through the input/output interface 16. When necessary information can be acquired through the input/output interface 16, the database 12 might not be used.

The operation unit 18 includes a keyboard and a pointing device such as a mouse and functions as a user interface for accepting various items specified by the user. The operation unit 18 may include a touch panel.

### First Embodiment of Construction Repair Support Apparatus

FIG. 2 is a block diagram illustrating a first embodiment of a construction repair support apparatus according to the present invention.

The construction repair support apparatus of the first embodiment illustrated in FIG. 2 is formed of the processor 10, the database 12, and the output unit 14 of the construction repair support apparatus 1 having the hardware configuration illustrated in FIG. 1, and the processor 10 functions as the information acquisition unit 20, the repair design information generation unit 22, and the determination basis generation unit 24.

The information acquisition unit 20 that functions as an input unit acquires from the database 12, construction information concerning a desired construction and damage information concerning damage in the construction in accordance with a selection instruction from the user.

### Construction Information

Construction information includes at least one of drawing information (for example, CAD (computer-aided design) information) about a construction, three-dimensional information that indicates the entire construction, a two-dimensional image (captured image) that shows a local part of a construction, or text information concerning a construction. Three-dimensional information is, for example, a three-dimensional image, three-dimensional CAD information, or three-dimensional point cloud data.

Further, construction information includes at least one of structural information, repair history information, environmental information, or monitoring information about a construction.

Examples of structural information and so on about a construction when the construction is a bridge are listed below.
Structural information about the construction: the form of bridge (for example, a truss bridge, an arch bridge, or a suspension bridge), the bridge length, the type of work (for example, superstructure work or substructure work), and the year of erection
Repair history information: the type of repair and a repair method (for example, crack filling work or concrete re-pouring work)
Environmental information: the position of erection, the volume of traffic, the climate, and a disaster history
Monitoring information: the results of measurement by a vibrometer that measures vibrations of the construction and by a stress meter that measures stress on the construction, the types of sensors including the vibrometer, the stress meter, and a camera that captures an image of the construction, and the positions of sensors

### Damage Information

Damage information concerning damage in a construction includes at least one of the damage type, the damage shape, the degree of damage, the degree of development of damage, the damaged region, the damage position, or similar damage.

Examples of damage types are listed below.
Typical damage in concrete members: cracks, peeling/exposure of reinforcing rods, water leakage/free lime, and concrete bulges
Typical damage in steel members: corrosion, fractures, ruptures, and loosening/falling off

The repair design information generation unit 22 generates repair design information concerning a repair of damage in a construction on the basis of construction information concerning the construction and damage information acquired by the information acquisition unit 20.

### Repair Design Information

Repair design information includes at least one of the cause of damage in a construction, a countermeasure method, the degree of soundness, the necessity of repair, degradation prediction, or a countermeasure category.

The types of the cause of damage include fatigue, salt damage, frost damage, an alkali-aggregate reaction, and neutralization in a case of concrete members and fatigue and material degradation in a case of steel members.

Examples of a countermeasure method include a pouring-into-crack method, a concrete protection method, a cross-section repair method, an electric anticorrosion method, and floor slab concrete re-pouring work.

As indicators of the degree of soundness, various indicators are specified by the country and local governments and, for example, indicators indicating diagnosis results at four levels from I to IV are specified in the road/bridge periodic inspection guidelines (February, 2019) established by the Ministry of Land, Infrastructure, Transport and Tourism.

As a countermeasure category, for example, the following categories are specified in the bridge periodic inspection guidelines (March, 2019) established by the Ministry of Land, Infrastructure, Transport and Tourism.
A: Repairs are not necessary.
B: Repairs need to be made in accordance with the circumstances.
C1: Repairs and so on need to be immediately made from the viewpoint of preventive maintenance.
C2: Repairs and so on need to be immediately made from the viewpoint of the safety of the bridge structure.
E1: An emergency response needs to be made from the viewpoint of the safety of the bridge structure.
E2: An emergency response needs to be made for other purposes.
M: A response needs to be made by carrying out maintenance work.
S1: A close investigation needs to be carried out.
S2: A follow-up investigation needs to be carried out.

Although usually a person in charge of diagnosis visually inspects a damaged location of a construction in proximity to the construction, conducts a hammering test or other tests as necessary, and creates from the damage state and so on, repair design information (inference of the cause of damage, selection of a countermeasure method, determination of the degree of soundness, determination of the necessity of repair, degradation prediction, selection of a countermeasure category, and so on), the repair design information generation unit 22 in the present invention automatically generates repair design information on the basis of construction information and damage information concerning the construction.

The repair design information generation unit 22 can be formed of, for example, a trained model (first learning model) for which machine learning has been performed by using data sets of learning data including pairs of construction information and damage information, and repair design information corresponding to the construction information and damage information, and in response to input of construction information and damage information, outputs repair design information corresponding to the construction information and damage information as an inference result. Note that the repair design information generation unit 22 need not automatically generate repair design information by the first learning model and may automatically generate repair design information with an algorithm for generating repair design information.

The determination basis generation unit 24 extracts and generates information that contributes to generation of the repair design information by the repair design information generation unit 22, as determination basis information for the repair design information. The determination basis information includes at least one of damage information, construction information, or environmental information.

The repair design information generated by the repair design information generation unit 22 is output to the output unit 14 and displayed in a repair design determination result presentation section 14A of the output unit 14.

Similarly, the determination basis information generated by the determination basis generation unit 24 is output to the output unit 14 and displayed in a repair design determination basis presentation section 14B of the output unit 14.

Note that in FIG. 2, the repair design information generation unit 22 may include a trained model (second learning model) that performs a damage information generation process, and the second learning model may output, in response to input of a two-dimensional image of a construction, damage information about the construction. In this case, the repair design information generation unit 22 need not receive damage information about the construction from the information acquisition unit 20 and can use damage information output from the second learning model in response to input of an input image, that is, a two-dimensional image of the construction included in the construction information.

Further, in the first embodiment of the construction repair support apparatus, the database 12 need not be provided, and the information acquisition unit 20 can acquire necessary information from an external device or a network through the input/output interface 16.

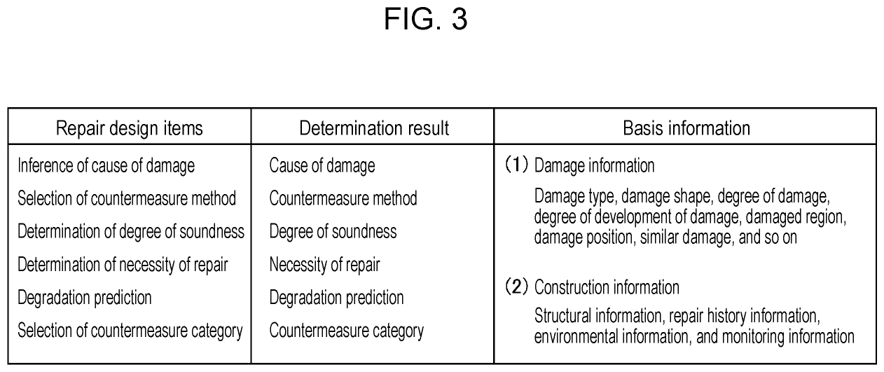

FIG. 3 is a table illustrating a list of determination results and determination basis information for various repair design items.

Although only with the repair design information presented in the repair design determination result presentation section 14A, the user may be unable to understand or be convinced of the determination basis for the repair design information, when repair design determination basis information is presented together with the repair design determination result as described above, the user can understand or be convinced of the determination basis for the repair design information.

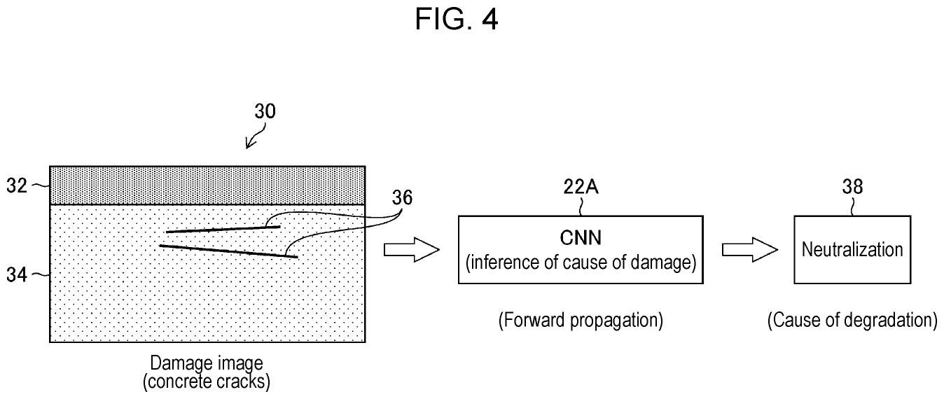

FIG. 4 is a diagram illustrating a flow in which a CNN (convolutional neural network) infers a determination result for a cause of damage (forward propagation).

In FIG. 4, when the repair design information generation unit 22 and the determination basis generation unit 24 are formed of a CNN 22A, as an input image, a damage image 30 is input to the CNN 22A that functions as the repair design information generation unit.

The CNN 22A infers repair design information concerning damage in the construction from features of the damage image 30 and outputs a determination result (repair design information). The damage image 30 in this example is a captured image 34 of a construction in which concrete cracks 36 occur along a steel member 32 (or a captured image on which a damage diagram showing cracks is superimposed and displayed), and the determination result is neutralization 38. The neutralization 38 is one of the causes of degradation (classes) and has external appearance features including cracks, rust, and concrete peeling along the axial direction of a steel member.

The CNN 22A outputs the neutralization 38 as the determination result from the above-described feature of the damage image 30.

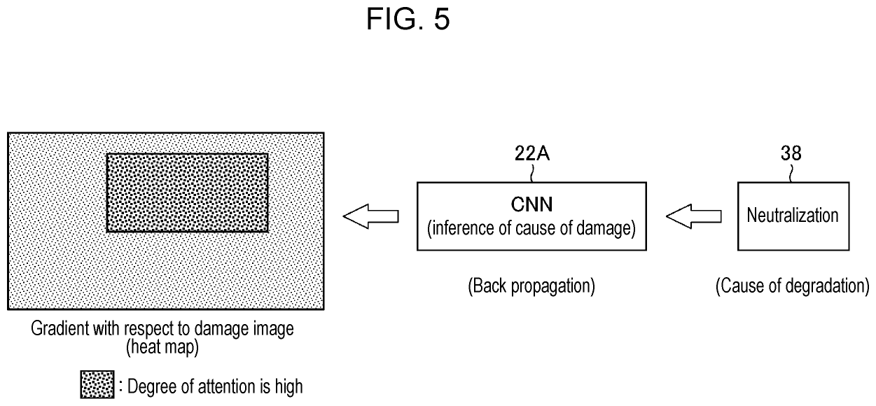

FIG. 5 is a diagram illustrating a flow in which the CNN infers from the determination result for the cause of damage, the determination basis for the determination result (back propagation).

In FIG. 5, when the repair design information generation unit 22 and the determination basis generation unit 24 are formed of the CNN 22A, the CNN 22A that functions as the determination basis generation unit calculates the calculation process for the output result backward and extracts determination basis information that affects the output result. In this example, the CNN 22A obtains a heat map 39 corresponding to the damage image 30 (FIG. 4).

As the heat map creation method, various methods are available and when, for example, Grad-CAM (Gradient-weighted Class Activation Mapping) is used, the gradient is calculated backward so as to maximize the probability value of the neutralization 38 that is the determination result and the heat map 39 is obtained as the determination basis for the neutralization 38. Alternatively, CAM, which is a base method for Grad-CAM, can be used. Further, as another method for creating a heat map (visualizing a region to which attention is to be paid) by the CNN, Attention is available.

In the heat map 39 illustrated in FIG. 5, a darker region is a region of a high degree of attention.

Therefore, the neutralization 38 can be presented as repair design information, and the heat map 39 can be presented as determination basis information therefor.

A heat map for a cause of degradation other than the neutralization 38 can be similarly calculated.

Further, a determination result and the determination basis can be cross-referenced to each other.

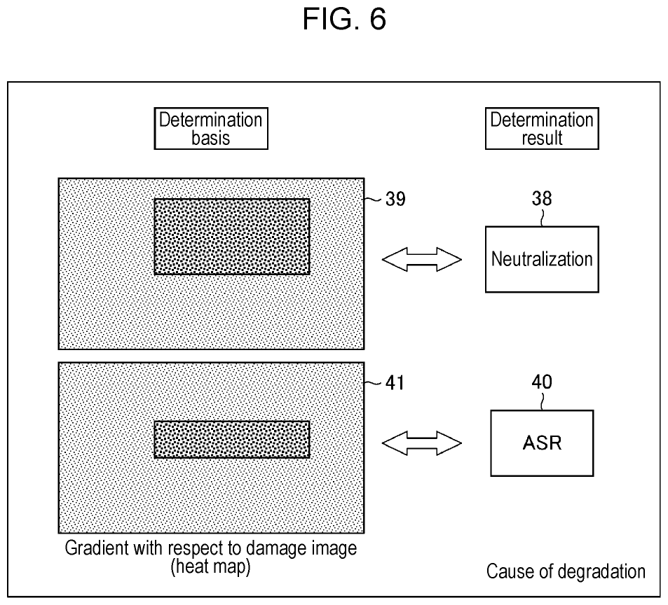

FIG. 6 is a diagram illustrating cross-reference relationships between determination results and determination bases.

In FIG. 6, when the user selects a cause of degradation, that is, the neutralization 38 or an ASR (alkali silica reaction) 40 presented in the determination result presentation section 14A, the processor 10 causes a corresponding heat map, that is, the heat map 39 or a heat map 41, to be displayed in the determination basis presentation section 14B. An ASR is one of the causes of degradation and has external appearance features including bulging cracks (in a restricted direction and having a hexagonal pattern), gel, and discoloration.

In response to the user giving an instruction for selecting a point (coordinates) on the heat map 39 or 41 presented in the determination basis presentation section 14B, the processor 10 can calculate estimated contribution percentages of the respective causes of degradation in accordance with the values on the heat map 39 or 41 and display the estimated contribution percentages in the determination result presentation section 14A together with the causes of degradation. For example, for a certain point on the heat map, 20% and 80% can be displayed for the neutralization and the ASR respectively.

Note that the method of presenting a determination basis as a heat map created by using, for example, Grad-CAM can be used for other than images.

### First Example of Determination Basis Presentation

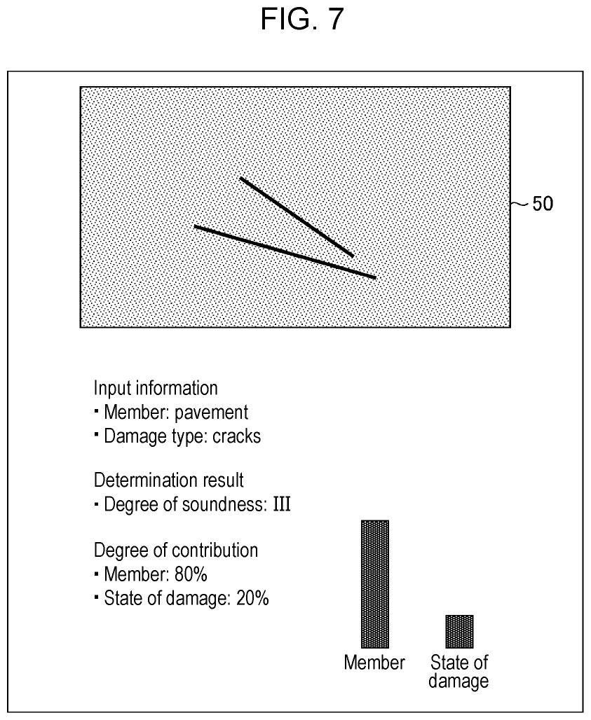

FIG. 7 is a diagram illustrating a first example of determination basis presentation displayed on the output unit.

In FIG. 7, the repair design determination result is a degree of soundness III. The degree of soundness III corresponds to a determination category “prompt action stage” and is a determination category that is defined as a state in which a prompt action is to be taken because of the possibility that the function of the road or bridge is impaired.

As the determination basis for this determination result, a damage image 50 is presented, and as input information, text information concerning the construction, that is, a member (pavement) and a damage type (cracks), is presented.

In the first example of determination basis presentation, in response to acquiring a plurality of pieces of determination basis information for the degree of soundness III, the processor 10 calculates degree-of-contribution information that includes a degree of contribution indicating the percentage of contribution of each of the plurality of pieces of determination basis information to generation of the degree of soundness III, by using heat maps as described above. In this example, as pieces of degree-of-contribution information for the member and the state of damage, the processor 10 calculates a degree of contribution 80% for the member and a degree of contribution 20% for the state of damage and causes these pieces of degree-of-contribution information to be displayed.

In the example illustrated in FIG. 7, the pieces of degree-of-contribution information for the member and the state of damage are displayed as numerical values and bar charts.

### Second Example of Determination Basis Presentation

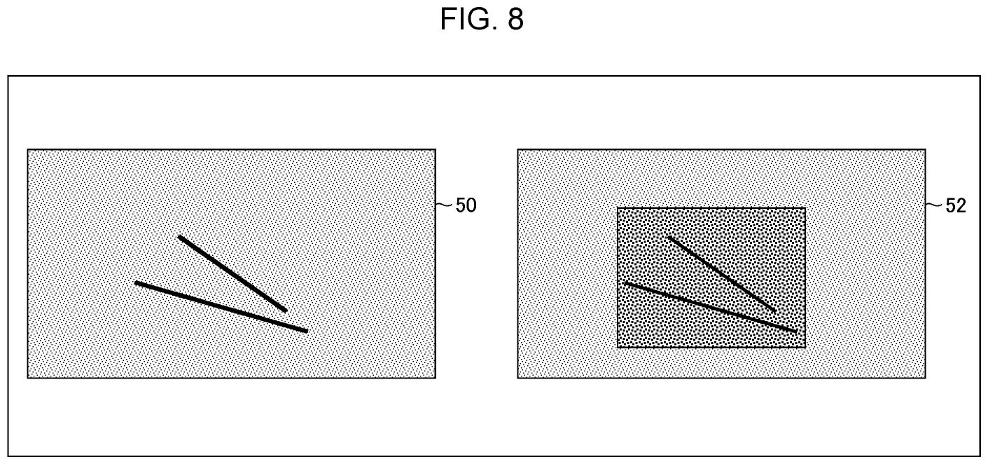

FIG. 8 is a diagram illustrating a second example of determination basis presentation displayed on the output unit.

In the second example of determination basis presentation illustrated in FIG. 8, the determination basis for a determination result is displayed as an image.

That is, as the determination basis for a determination result, the damage image 50 and a heat map 52 are displayed.

The heat map 52 is a heat map corresponding to the damage image 50 and obtained by the CNN 22A calculating the gradient backward so as to maximize the probability value of the determination result as illustrated in FIG. 5. It is preferable to display the heat map 52 so as to be color-coded or shaded in accordance with the values on the heat map to thereby allow region information about a region (for example, a region having a high or low degree of attention) to which attention is to be paid with respect to the determination result, to be visually identified at a plurality of levels. Note that the number of levels in region information according to the degree of attention can be set as desired.

### Third Example of Determination Basis Presentation

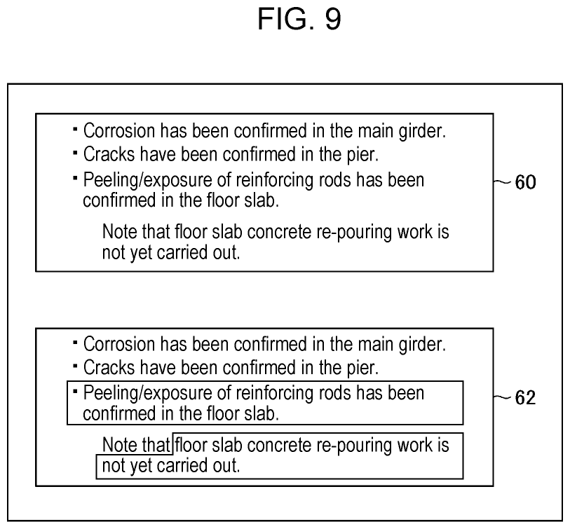

FIG. 9 is a diagram illustrating a third example of determination basis presentation displayed on the output unit.

In the third example of determination basis presentation illustrated in FIG. 9, for example, the determination basis for a determination result is displayed as text.

In FIG. 9, in response to input of text information 60 illustrated in FIG. 9 concerning a construction to the repair design information generation unit 22, the repair design information generation unit 22 extracts from the text information 60, text that serves as keywords corresponding to repair design information (in this example, “floor slab concrete re-pouring work is not yet carried out”) and extracts text that serves as keywords corresponding to determination basis information (in this example, “peeling/exposure of reinforcing rods has been confirmed in the floor slab”).

“Floor slab concrete re-pouring work” is a repair method that is performed when the floor slab of a bridge is significantly damaged and the floor slab is unable to be satisfactorily maintained with temporary measures or a maintenance method.

The processor 10 causes the output unit 14 to display the text information 60 and text information 62 in which the extracted text is highlighted.

Although the text information 62 in which the extracted text is highlighted by boxing the extracted text is displayed in this example, alternatively, the extracted text may be highlighted by coloring the extracted text, for example, red. Instead of the text information 62, text information, such as “repair design information: floor slab concrete re-pouring work” and “determination basis information: peeling/exposure of reinforcing rods in floor slab”, may be generated and displayed.

### Three-Dimensional Display

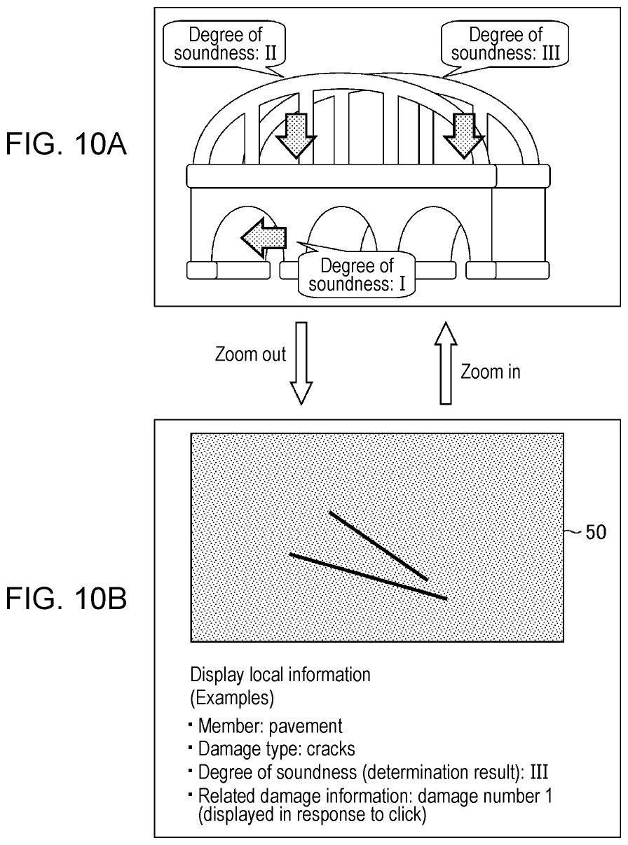

FIGS. 10A and 10B are diagrams illustrating switching between overall display of a construction displayed three-dimensionally and local display.

Construction information includes three-dimensional information (in this example, a three-dimensional image) that indicates the entire construction, and the processor 10 can cause the output unit 14 to three-dimensionally display the construction on the basis of the three-dimensional image acquired by the information acquisition unit 20.

FIG. 10A illustrates a display screen of overall display on the output unit 14 on which the construction is displayed as a three-dimensional image.

On the three-dimensional image in overall display, locations for which the determination results of repair design information are obtained are highlighted with, for example, indicators such as arrows and/or highlighting. The processor 10 can cause the output unit 14 to display, on the basis of positional information about a location for which the determination result is obtained, repair design information associated with the positional information.

FIG. 10B illustrates a display screen of local display on the output unit 14 on which a certain one location of the construction for which the determination result is obtained is displayed.

Local display can be performed by displaying a two-dimensional image (in this example, the damage image 50) showing a local part of the construction.

As illustrated in FIG. 10B, the processor 10 causes the output unit 14 to, for example, display the repair design determination result (in this example, the degree of soundness III), display a member (pavement) and a damage type (cracks) that are information contributing to generation of the degree of soundness III, and display related damage information (damage number 1) together with local display of the construction.

The processor 10 can switch between the overall display of the construction illustrated in FIG. 10A and the local display of the construction illustrated in FIG. 10B in response to accepting an instruction from the user.

In response to accepting switching of display in the overall display state and positional information about damage to be locally displayed, the processor 10 switches display on the output unit 14 from the overall display (FIG. 10A) to the local display (FIG. 10B).

For example, in response to the user operating the mouse and clicking on the position of damage, on the overall display screen, that is to be locally displayed (or on the display position of a determination result displayed in association with the position of damage), the processor 10 switches from the overall display (FIG. 10A) to the local display (FIG. 10B) that includes, for example, an image of the specified position of damage. In response to accepting a zooming operation for zooming in performed by, for example, a wheel operation of the mouse, the processor 10 can transition the display to the local display (FIG. 10B) while enlarging the overall display (FIG. 10A).

In contrast, in response to accepting switching from the local display to the overall display in the local display state, the processor 10 switches from the local display (FIG. 10B) to the overall display (FIG. 10A). For example, in response to accepting a zooming operation for zooming out performed by, for example, a wheel operation of the mouse, the processor 10 can transition the display to the overall display (FIG. 10A) while reducing the local display (FIG. 10B).

Note that a user operation for switching between overall display and local display is not limited to the above-described operation method using a mouse. For example, when the operation unit 18 includes a touch panel, an instruction for switching between overall display and local display can be given by, for example, a tap operation and pinch-in and pinch-out operations on the touch panel.

In response to the user inputting a request for viewing the details of damage information on the local display screen (for example, in response to a click on “damage number 1” in FIG. 10B), the processor 10 can cause other information concerning damage corresponding to “damage number 1” (for example, the damage shape, the degree of damage, and the degree of development of damage) to be displayed. When pieces of past damage information about the same damage are saved in the database 12, the degree of development of damage can be obtained on the basis of the difference between pieces of damage information at a plurality of time points (a piece of past damage information and a piece of current damage information), as information indicating the degree of a change over time in the pieces of damage information between the plurality of time points.

The local display is not limited to, for example, the damage image 50 that is a two-dimensional image and can be performed by enlarging a three-dimensional image that shows the entire construction and displaying a part of the three-dimensional image. Instead of a three-dimensional image, for example, overall display of a construction may be performed on the basis of other three-dimensional information, such as three-dimensional CAD (computer-aided design) data or three-dimensional point cloud data, about the construction.

### List Display

Repair design information generated by the repair design information generation unit 22 illustrated in FIG. 2 and determination basis information generated by the determination basis generation unit 24 illustrated in FIG. 2 can be associated with each other in a list.

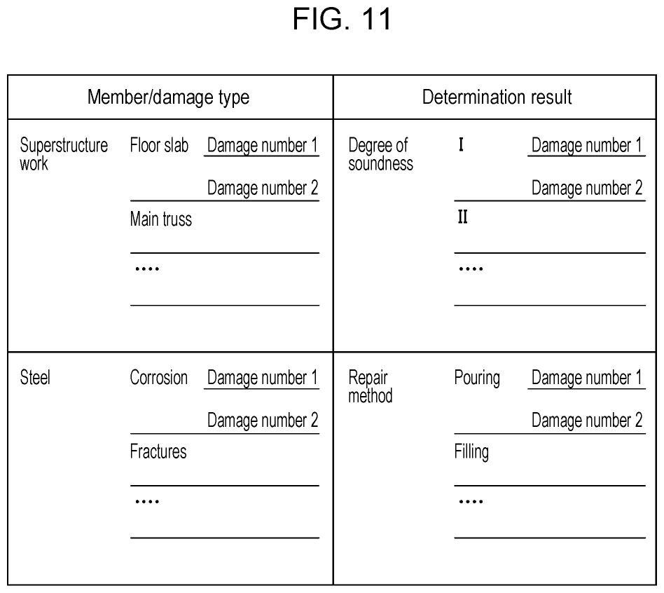

FIG. 11 is a diagram illustrating an example of a list of text information of repair design information and text information of determination basis information that are associated with each other in the list. The determination result for damage in a construction is one form of repair design information, and the member/damage type is one form of determination basis information.

In response to the user inputting an instruction for list display, the processor 10 can cause the output unit 14 to display the list as illustrated in FIG. 11.

In response to the user inputting an instruction for specifying, for example, a member/damage type or a determination result for damage, the processor 10 can perform sorting for the list, and in response to a click on, for example, “floor slab damage number 1” on the list illustrated in FIG. 11, the processor 10 can cause, for example, a damage image, a damage diagram, and text information corresponding to “floor slab damage number 1” to be displayed.

### Second Embodiment of Construction Repair Support Apparatus

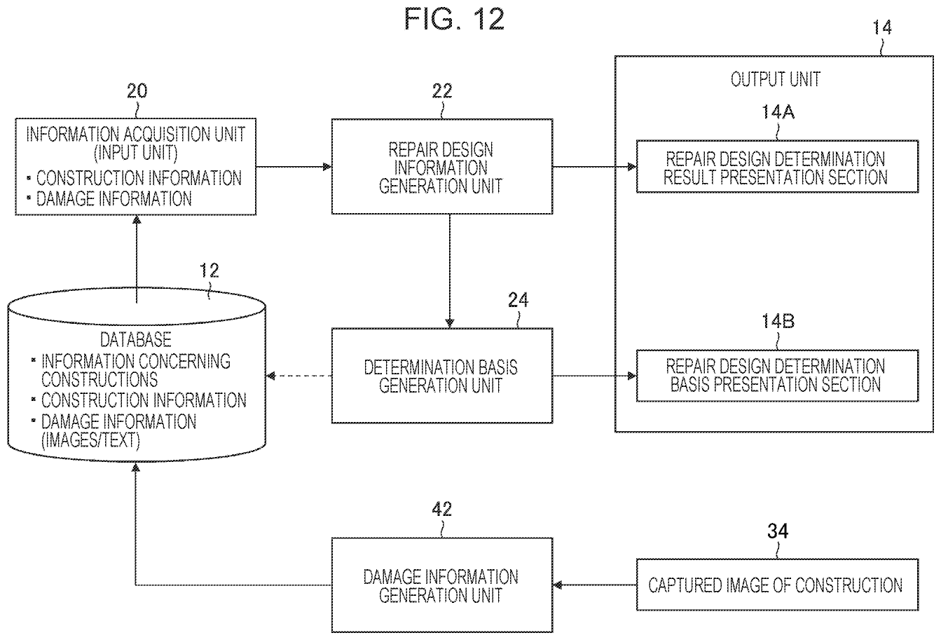

FIG. 12 is a block diagram illustrating a second embodiment of a construction repair support apparatus according to the present invention. In FIG. 12, a part common to the first embodiment of the construction repair support apparatus illustrated in FIG. 2 is assigned the same reference numeral and a detailed description thereof will be omitted.

The construction repair support apparatus of the second embodiment illustrated in FIG. 12 is different from the construction repair support apparatus of the first embodiment in that a damage information generation unit 42 is added.

In response to input of a captured image 34 of a construction, the damage information generation unit 42 generates, on the basis of the captured image 34, damage information including the type of damage in the construction present in the captured image 34, the damage shape, the degree of damage, the damaged region, and the damage position.

The damage information generation unit 42 can be formed of, for example, a trained model (third learning model) for which machine learning has been performed by using data sets of learning data including pairs of captured images of damage in constructions, and damage information concerning the damage in the captured images, and in response to input of the captured image 34 of a test target construction, outputs damage information concerning damage in the captured image as an inference result. Note that the damage information generation unit 42 need not automatically generate damage information by the third learning model and may automatically generate damage information with a detection algorithm for detecting damage information.

The damage information generated by the damage information generation unit 42 can be saved in the database 12 in association with construction information (for example, the captured image 34) corresponding to the damage information.

Further, repair design information generated by the repair design information generation unit 22 illustrated in FIG. 2 and determination basis information generated by the determination basis generation unit 24 illustrated in FIG. 2 may be associated with each other and saved in the database 12. Accordingly, recalculation is not necessary in the repair design information generation unit 22 or the determination basis generation unit 24, which is an advantage.

### Construction Repair Support Method

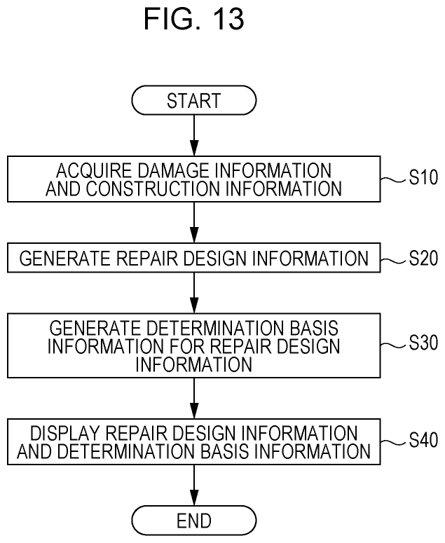

FIG. 13 is a flowchart illustrating an embodiment of a construction repair support method according to the present invention. The processes in respective steps illustrated in FIG. 13 are performed by the processor 10 of the construction repair support apparatus 1 illustrated in FIG. 1.

In FIG. 13, the processor 10 acquires, in accordance with a selection instruction from the user, construction information concerning a desired construction and damage information concerning damage in the construction from the database 12 (step S10, damage information acquisition process).

The processor 10 generates repair design information concerning a repair of the damage in the construction on the basis of the acquired construction information and damage information (step S20, repair design information generation process).

The processor 10 generates automatically or in response to an instruction for generation from the user, information that contributes to generation of the repair design information generated in step S20, as determination basis information for the repair design information (step S30, determination basis generation process).

The processor 10 outputs to and causes the output unit 14 to display the repair design information generated in step S20 and the determination basis information generated in step S30 (step S40, display process). Note that display of the repair design information and display of the determination basis information may be simultaneously performed on the same screen, or any one of the repair design information or the determination basis information may be displayed in accordance with a selection instruction from the user.

### Others

In the embodiments, the hardware configuration of the processing units including the CPU that perform various types of processing is implemented as various processors as described below. The various processors include a CPU (central processing unit) that is a general-purpose processor executing software (program) to function as various processing units, a programmable logic device (PLD), such as an FPGA (field-programmable gate array), that is a processor for which the circuit configuration can be changed after manufacturing, and a dedicated electric circuit, such as an ASIC (application-specific integrated circuit), having a circuit configuration that is designed only for performing a specific process.

One processing unit may be configured as one of the various processors or two or more processors of the same type or different types (for example, a plurality of FPGAs or a combination of a CPU and an FPGA). Further, a plurality of processing units may be configured as one processor. As the first example of configuring a plurality of processing units as one processor, a form is possible in which one or more CPUs and software are combined to configure one processor, and the processor functions as the plurality of processing units, a representative example of which is a computer, such as a client or a server. As the second example thereof, a form is possible in which a processor is used in which the functions of the entire system including the plurality of processing units are implemented as one IC (integrated circuit) chip, a representative example of which is a system on chip (SoC). As described above, regarding the hardware configuration, the various processing units are configured by using one or more of the various processors described above.

Further, the hardware configuration of the various processors is more specifically an electric circuit (circuitry) in which circuit elements, such as semiconductor elements, are combined.

Further, the present invention includes the construction repair support program that is installed in a computer to thereby cause the computer to function as the construction repair support apparatus according to the present invention, and a nonvolatile storage medium to which the construction repair support program is recorded.

Further, the present invention is not limited to the above-described embodiments and various modifications can be made without departing from the spirit of the present invention as a matter of course.

### REFERENCE SIGNS LIST

1 construction repair support apparatus
10 processor
11 memory
12 database
14 output unit
14A determination result presentation section
14B determination basis presentation section
16 input/output interface
18 operation unit
20 information acquisition unit
22 repair design information generation unit
22A CNN
24 determination basis generation unit
30, 50 damage image
32 steel member
34 captured image
36 concrete crack
38 neutralization
39, 41, 52 heat map
42 damage information generation unit
60, 62 text information
S10 to S40 step

What is claimed is:

1. A construction repair support apparatus comprising a processor,
the processor being configured to perform
an information acquisition process of acquiring construction information concerning a construction,
a repair design information generation process of generating repair design information concerning a repair of damage in the construction on the basis of the construction information and damage information concerning the damage in the construction,
a determination basis generation process of generating information that contributes to generation of the repair design information, as determination basis information for the repair design information, and
a display process of causing a display device to display the repair design information and the determination basis information.

2. The construction repair support apparatus according to claim 1, wherein
the processor is configured to acquire positional information about the damage in the construction, and cause the display device to display the repair design information in association with the positional information.

3. The construction repair support apparatus according to claim 2, wherein
the construction information includes three-dimensional information that indicates the entire construction, and
the processor is configured to cause the display device to display the construction three-dimensionally on the basis of the three-dimensional information, and cause the repair design information to be displayed at a corresponding position on the three-dimensionally displayed construction, on the basis of the positional information about the damage.

4. The construction repair support apparatus according to claim 3, wherein
the processor is configured to perform a process of accepting switching between overall display and local display of the construction, and
the processor is configured to
in response to accepting switching from the overall display to the local display and the positional information about the damage, switch display on the display device from the overall display of the construction based on the three-dimensional information to the local display that includes an image of a position indicated by the positional information about the damage, and cause the display device to display the determination basis information associated with the positional information about the damage, and
in response to accepting switching from the local display to the overall display, switch display on the display device to the overall display, and cause the display device to display the repair design information in association with the positional information about the damage.

5. The construction repair support apparatus according to claim 1, further comprising
a database that stores the construction information and the damage information, wherein
the processor is configured to perform a damage information generation process of generating the damage information on the basis of a two-dimensional image of the construction included in the construction information, and store the damage information in the database in association with the construction information, and
in the information acquisition process, the construction information and the damage information associated with the construction information are acquired from the database.

6. The construction repair support apparatus according to claim 1, further comprising
a database that stores the construction information, wherein
in the information acquisition process, the construction information is acquired from the database, and
in the repair design information generation process,
the damage information is generated on the basis of a two-dimensional image of the construction included in the construction information, the construction information being acquired in the information acquisition process, and
the repair design information concerning a repair of the damage in the construction is generated on the basis of the construction information and the damage information.

7. The construction repair support apparatus according to claim 1, wherein
in response to acquiring a plurality of pieces of determination basis information including the determination basis information, the processor is configured to calculate pieces of degree-of-contribution information that respectively indicate percentages of contribution of the plurality of pieces of determination basis information to generation of the repair design information, and cause the display device to display the pieces of degree-of-contribution information respectively corresponding to the plurality of pieces of determination basis information.

8. The construction repair support apparatus according to claim 1, wherein
the determination basis information includes region information about a region, on the construction, to which attention is to be paid.

9. The construction repair support apparatus according to claim 1, wherein
in the repair design information generation process, the repair design information is generated on the basis of pieces of damage information at a plurality of time points, and
the determination basis information includes a degree of a change over time in the pieces of damage information between the plurality of time points.

10. The construction repair support apparatus according to claim 1, wherein
the processor is configured to perform a process of accepting specifying of the repair design information by a user, and in response to accepting specifying of the repair design information, cause the display device to display the determination basis information corresponding to the repair design information.

11. The construction repair support apparatus according to claim 1, wherein
the processor is configured to perform a process of accepting specifying of the determination basis information by a user, and in response to accepting specifying of the determination basis information, cause the display device to display the repair design information corresponding to the determination basis information.

12. The construction repair support apparatus according to claim 1, wherein
the processor includes a first learning model configured to perform the repair design information generation process, and
the first learning model outputs the repair design information in response to input of the construction information or input of the construction information and the damage information.

13. The construction repair support apparatus according to claim 12, wherein
in the determination basis generation process performed by the processor, a calculation process for an output result of the first learning model is traced back and the determination basis information that affects the output result is extracted.

14. The construction repair support apparatus according to claim 13, wherein
in the determination basis generation process performed by the processor, information visualizing a region to which attention is to be paid of the first learning model, is generated corresponding to information input to the first learning model, as the determination basis information.

15. The construction repair support apparatus according to claim 14, wherein
in the determination basis generation process performed by the processor, a heat map is generated as the information visualizing a region to which attention.

16. The construction repair support apparatus according to claim 15, wherein
in the determination basis generation process performed by the processor, the heat map is generated using Grad-CAM, CAM or Attention.

17. The construction repair support apparatus according to claim 5, wherein
the processor includes a second learning model configured to perform the damage information generation process, and
the second learning model outputs the damage information about the construction in response to input of a two-dimensional image of the construction.

18. The construction repair support apparatus according to claim 1, wherein
the construction information includes at least one of drawing information about the construction, three-dimensional information that indicates the entire construction, a two-dimensional image that shows a local part of the construction, or text information concerning the construction.

19. The construction repair support apparatus according to claim 1, wherein
the construction information includes at least one of structural information, repair history information, environmental information, or monitoring information about the construction.

20. The construction repair support apparatus according to claim 1, wherein
the repair design information includes at least one of a cause of damage, a countermeasure method, a degree of soundness, necessity of repair, degradation prediction, or a countermeasure category.

21. The construction repair support apparatus according to claim 1, wherein
the determination basis information includes at least one of the damage information, the construction information, or environmental information.

22. The construction repair support apparatus according to claim 1, wherein
the damage information includes at least one of a damage type, a damage shape, a degree of damage, a degree of development of damage, a damaged region, a damage position, or similar damage.

23. A construction repair support method for a processor to perform
a step of acquiring construction information concerning a construction,
a step of generating repair design information concerning a repair of damage in the construction on the basis of the construction information and damage information concerning the damage in the construction,
a step of generating information that contributes to generation of the repair design information, as determination basis information for the repair design information, and
a step of causing a display device to display the repair design information and the determination basis information.

24. A non-transitory, computer-readable tangible recording medium to which a program for causing, when read by a computer, the computer to execute the construction repair support method according to claim 23 is recorded.
